(19) United States
(12) Patent Application Publication
(10) Pub. No.: US 2003/0015794 A1
(43) Pub. Date: Jan. 23, 2003

(54) Semiconductor device with an ohmic contact and method of manufacturing the same

(76) Inventors: Liann-Be Chang, Tao-Yuan (TW); Bor-Jen Wu, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/191,066

(22) Filed: Jul. 10, 2002

(30) Foreign Application Priority Data
Jul. 23, 2001 (TW) 090117960

(51) Int. Cl. H01L 23/48; H01L 23/52; H01L 29/40

(52) U.S. Cl. 257/744

(57) ABSTRACT

A semiconductor device with an ohmic contact and method of manufacturing the same is disclosed. The semiconductor device comprises a substrate, a p-type gallium nitride layer provided on said substrate, and a p-type indium gallium nitride (InₓGa₁₋ₓN) layer provided on said p-type gallium nitride layer, so as to form an excellent interface with low ohmic contact resistance between a semiconductor and a metal layer. A light-emitting device with a low ohmic contact resistance and a method of manufacturing the same. Wherein the light emitting device comprises a substrate, a buffer layer on the substrate, an n-type cladding layer on the buffer layer, an active layer on the n-type cladding layer, a p-type cladding layer on the active layer, a p-type indium gallium nitride (InₓGa₁₋ₓN) layer on the p-type cladding layer, and a metal layer on the indium gallium nitride (InₓGa₁₋ₓN) layer to form an excellent interface with low ohmic contact resistance between a semiconductor and a metal layer.

### BACKGROUND OF THE INVENTION

1. Field of the Invention

The present invention relates to a semiconductor device with an ohmic contact, especially in providing a p-type indium gallium nitride (InₓGa₁₋ₓN) layer on a p-type gallium nitride (GaN) layer information of an excellent interface with a low ohmic contact resistance, and a method for manufacturing, such items as light emitting diodes, laser diodes, and microwaves device.

2. Description of the Prior Art

As well known to those skilled in the art, in order to produce semiconductor devices, such as optical devices (i.e. light emitting diodes, laser diodes, or microwave devices), it is important to provide an optimum ohmic contact at the junction between a semiconductor layer and a metal layer. For the semiconductors composed of III-V Group compounds, the characters of an optimum ohmic contact comprise smooth surface morphology, good thermal stability, simple manufacture, low contact resistance, high production yield, and good adhesion. The Gallium nitride based semiconductor is utilized as a suitable material of light-emitting devices, such as light-emitting diode and laser diode, because the Gallium nitride based semiconductor has a direct band gap, wherein the range of the band gap of the Gallium nitride based semiconductor is 1.95 eV to 6 eV. The Gallium nitride based semiconductor consists of Gallium nitride based compounds, such as gallium nitride, gallium aluminum nitride (GaAlN), indium gallium nitride (InGaN), and indium aluminum gallium nitride (InAlGaN).

A prior art technique for a formation of such an ohmic contact for optical devices may be referred to in U.S. Pat. No. 5,563,422, entitled “Gallium Nitride-Based III-V Group Compound Semiconductor Device and Method of Producing the Same”. In the above-mentioned U.S. patent, since some problems, due to nonconductive characteristics of a transparent substrate or a sapphire substrate, occur in an n-type ohmic contact, an electrode covered with a metal thin film has taken the place of a transparent electrode. However, the technique disclosed in the above U.S patent is problematic in that the electrode, covered with the metal thin film, fails to allow light to effectively pass through. In Material Research Society Symposium Proceeding 449, 1061, 1997, T. Kim and et al. reported that a required specific contact resistance Rc for an optimal ohmic contact, formed in an Ni/Cr/Au model through a heat treatment process for 30 minutes and at 500° C., is 8.3×10⁻² Ωcm⁻². In the same Proceeding 449, 1093, 1197, J. T. Trexler and et al. reported that a required specific contact resistance for an optimal ohmic contact, formed in a Cr/Au model through a heat treatment process at 900° C. for 15 minutes, is 4.3×10⁻¹ Ωcm⁻².

In the prior art, there was a plurality of reference disclosing a formation of Ni or Pt ohmic contact in a metal thin film for optical devices. However, according to the prior art reference, it is impossible to perform a formation of p-type gallium nitride ohmic contacts on a metal thin film.

### SUMMARY OF THE INVENTION

As above-mentioned, such a defective ohmic contact, formed on a metal thin film, causes serious problems in a continuous wave mode of gallium nitride light emit diodes (GaN LEDs) and laser diodes (LDs). In an effort to overcome the above-mentioned problems, the inventors of this invention have actively studied a formation of ohmic contact by interposing a p-type InₓGa₁₋ₓN layer between a p-type gallium nitride-based III-V group layer and a metal electrode. The above-mentioned structure and method of the present invention is different from that of p-type ohmic contact in Ni/Au or Ni/Cr/Au models, thus forming an ohmic contact with low resistance.

Therefore, according to the defects caused by using the method and device in the above-mentioned prior art, the present invention is to primarily provide a semiconductor device with a low ohmic contact resistance and a method of manufacturing the same, wherein a p-type InₓGa₁₋ₓN layer is formed on the p-type GaN layer to lower the ohmic contact resistance between a metal layer and a p-type GaN layer. By the addition of the p-type InₓGa₁₋ₓN layer on the p-type GaN layer of the semiconductor device, the energy band gap between the metal and semiconductor can be reduced effectively.

The present invention is also to provide a light emitting device with a low ohmic contact resistance and a method of manufacturing the same, wherein a p-type InₓGa₁₋ₓN layer is formed on the p-type GaN layer to lower the ohmic contact resistance between a metal layer and a p-type GaN layer.

It is an object of the present invention to provide a semiconductor device having a p-type InₓGa₁₋ₓN layer provided on a p-type gallium nitride layer in the device, and a method of manufacturing the same.

It is another object of this invention to provide an ohmic contact with low resistance in a semiconductor device, and a method of manufacturing the same.

It is an object of the present invention to provide a light-emitting device having a p-type InₓGa₁₋ₓN layer provided on a p-type gallium nitride layer, and a method of manufacturing the same.

It is a further object of this invention to provide a light emitting device with low ohmic contact resistance, and a method of manufacturing the same.

In accordance with the above-mentioned objects, the present invention relates to providing a semiconductor structure and a method of manufacturing the same, wherein the semiconductor structure comprises a substrate, a p-type GaN layer formed on the substrate, a p-type InₓGa₁₋ₓN layer formed on the p-type GaN layer, a metal layer provided on the p-type InₓGa₁₋ₓN layer.

Moreover, the present invention relates to providing a light emitting device structure and a method of manufacturing the same, wherein the light emitting device comprises a substrate, a buffer layer formed on said substrate, a n-type cladding layer formed on said buffer layer, an active layer formed on said n-type cladding layer, a p-type cladding layer formed on said active layer, a p-type InₓGa₁₋ₓN layer formed on said p-type cladding layer, a metal layer provided on said p-type InₓGa₁₋ₓN layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1B are cross-sectional view for showing the structure of the p-type semiconductor device using conventional, prior art techniques;

FIG. 2 is a cross-sectional view for showing the structure of the semiconductor device according to the example 1 in the present invention;

FIG. 3 is a side view for explaining the construction of a semiconductor device according to the example 2 in present invention;

FIGS. 4A to 4B are side views of the device for explaining a manufacturing process according to the example 2 in the present invention;

FIG. 5 is a schematic diagram for showing the measurement method of the present invention;

FIG. 6 is a current versus bias diagram for showing the electrical characteristic of the conventional p-type semiconductor device and that of the present invention; and

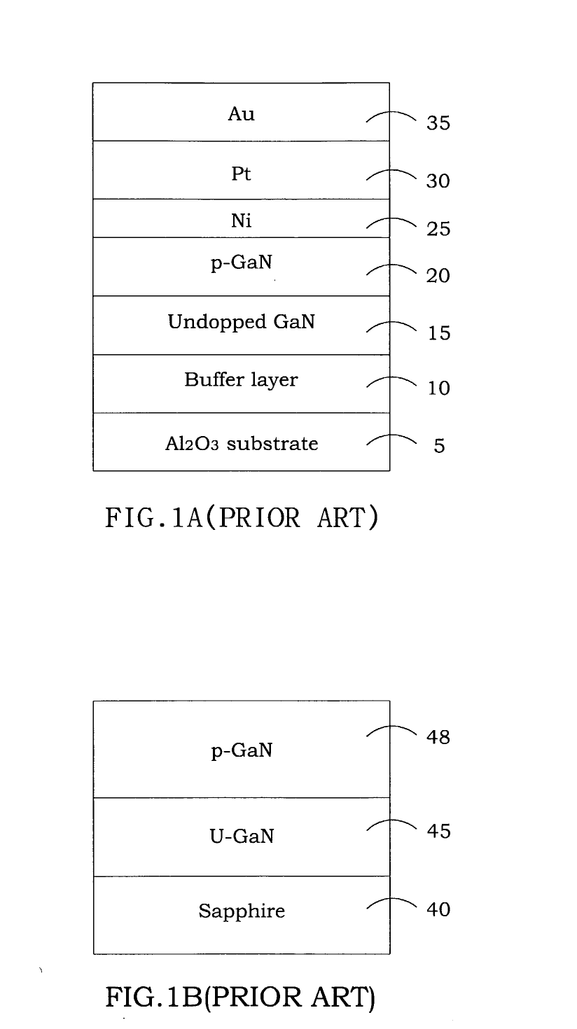

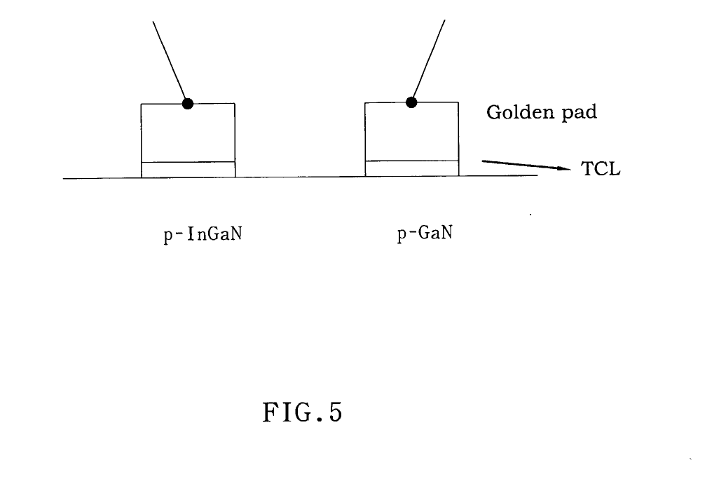

Table 1 is a diagram showing the result of the measurement in FIG. 5.

### DESCRIPTION OF THE PREFERRED EMBODIMENT

Some embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

### EXAMPLE 1

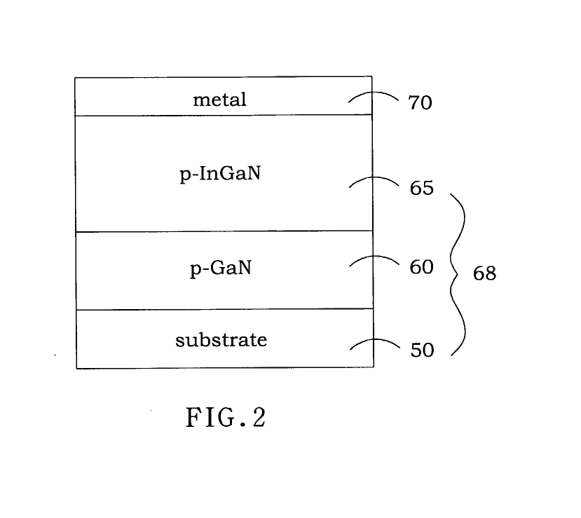

As shown in FIG. 2, first, a substrate 50 (the preferred material of the present invention is sapphire) is loaded in a reactor and held in a hydrogen flow at about 1050° C. for about 10 minutes, so that the surface of the substrate 50 is heated-cleaned. Next, a p-type GaN layer 60 is formed on the substrate 50 between 700 ° C.˜1200° C. The p-type GaN layer 60 is formed by MOCVD Metal Organic Chemical Vapor Deposition), LPE (Liquid Phase Epitaxy), MBE (Molecular Bean Epitaxy) or other conventional techniques, such as using NH₃ and TMG (trimethyl gallium) as the precursors and using CP₂Mg (biscyclopentadiene magnesium) or DMZn (dimethylzinc) as the precursor of the p-type dopant. The thickness of the p-type GaN layer 60 is about 10 nm to 2000 nm, and the preferred thickness is 200 nm.

Subsequently, a p-type indium gallium nitride (InₓGa₁₋ₓN) layer 65 is formed on the p-type GaN layer 60 by introducing TMI(trimethyl indium), TMG and NH₃ into the reactor. The thickness of the p-type InₓGa₁₋ₓN layer 65 is about 50 nm to 150 nm, and the preferred thickness is 100 nm. Importantly, the weight proportion of indium in the p-type InₓGa₁₋ₓN layer 65 is over 0.05%, and a GaN semiconductor 68 is formed.

The GaN semiconductor 68 formed by the above-mentioned processes is washed in an ultrasonic bath. The GaN semiconductor 68 is repeatedly washed by a plurality of washing liquids, such as trichloroethylene, acetone, methanol distilled water and so on, wherein the GaN semiconductor is washed at 50° C. for 5 minutes in each washing liquid. After the washing process, the GaN semiconductor 68 is dried through a hard baking process at 100° C. for 10 minutes to completely remove the moisture of the GaN semiconductor 68. A photoresist is coated onto the GaN semiconductor 68 by a spin coating process at 5,500 rpm. Thereafter, the GaN semiconductor 68 is subjected to a soft baking process at 85° C. for 15 minutes. In order to develop a mask pattern on the GaN semiconductor 68, a mask is disposed onto the GaN semiconductor 68, and the GaN semiconductor 68 is exposed to an ultraviolet ray for 60 seconds. After the exposure process, the GaN semiconductor 68 is subjected to a reverse baking process at 115° C., and to a developing process for about 40 seconds in a solution which is prepared by mixing a developing agent with distilled water.

Thereafter, a vapor deposition process is performed to form a metal layer 70 onto the p-type InₓGa₁₋ₓN layer 65 of the GaN semiconductor 68. During the vapor deposition process, at least one of the nickel (Ni), platinum (Pt), gold (Au), or the alloy is deposited onto the p-type InₓGa₁₋ₓN layer 65 of the GaN semiconductor 68, and the thickness of the deposition layer is about 200 nm to 1000 nm.

### EXAMPLE 2

(Epitaxy Process)

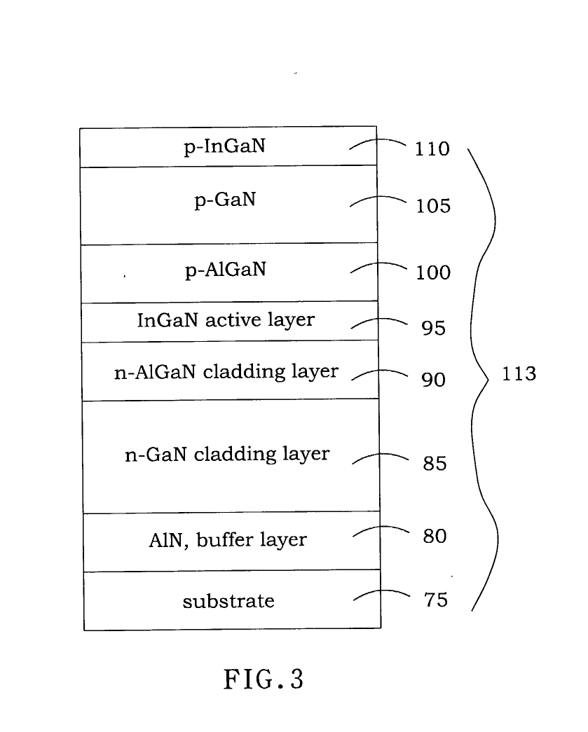

Referred to FIG. 3, a substrate 75 (the preferred material of the present invention is sapphire) is loaded in a reactor and held in a hydrogen flow at about 1050° C. for about 10 minutes for heated-cleaning the surface of the substrate 75.

The temperature of the substrate 75 is reduced to 600° C. NH₃ and TMA (trimethyl aluminum) are introduced into the reactor, wherein NH₃ is used as a nitrogen precursor and TMA (trimethyl aluminum) is used as an Al precursor. A buffer layer of AlN 80 is grown onto the substrate 75 by MOCVD (Metal Organic Chemical Vapor Deposition), LPE (Liquid Phase Epitaxy), MBE(Molecular Bean Epitaxy) or other conventional techniques, and the thickness of the AlN 80 is about 50 nm.

Subsequently, using NH₃ and TMG (trimethyl gallium) as precursors, a n-type GaN cladding layer 85 is grown under 700° C. to 1200° C., and the thickness of the n-type GaN cladding layer 85 is about 200 nm. At that time, Me-SiH₃ (methyl silane) is utilized as a precursor for n-type dopant.

TMA is further added to the above-described gases for growing an n-type AlGaN layer 90 doped with Si. Thus the thickness of the n-type AlGaN cladding layer 90 is about 200 nm.

Next, TMI (trimethyl indium), TMG and NH₃ are introduced into the reactor to form an InGaN active layer 95, wherein the InGaN active layer 95 is grown about 20 nm thick.

Subsequently, a p-type AlGaN cladding layer 100 is grown onto the InGaN active layer 95. The p-type AlGaN cladding layer 100 consists of the identical gases of the n-type cladding layer, except for Me-SiH₃, CP₂Mg and DMZn.

Next, the p-type GaN cladding layer 105 is grown onto the p-type AlGaN cladding layer 100, wherein the p-type GaN cladding layer 105 consists of the identical gases of the n-type GaN cladding layer except for Me-SiH₃, and CP₂ Mg or DMZn. The thickness of the p-type GaN cladding layer 105 is about 10 nm to 2000 nm. Preferably, the thickness of the p-type GaN cladding layer 105 is 400 nm.

finally, a p-type indium gallium nitride (InₓGa₁₋ₓN) layer 110 is formed on the p-type GaN cladding layer 105 by introducing TMI (trimethyl indium), TMG and NH₃ into the reactor. The thickness of the p-type InₓGa₁₋ₓN layer 110 is about 5 nm to 1000 nm, and preferably, the thickness of the p-type InₓGa₁₋ₓN layer 110 is 100 nm. Importantly, the percentage of indium in the p-type InₓGa₁₋ₓN layer 110 is preferred over 0.05 weight percent. Thus, a GaN semiconductor 113 is formed by laminating each above-mentioned layer.

(Light Emitting Device Process)

One character of this present invention is forming a light-emitting device forming process as described hereinafter.

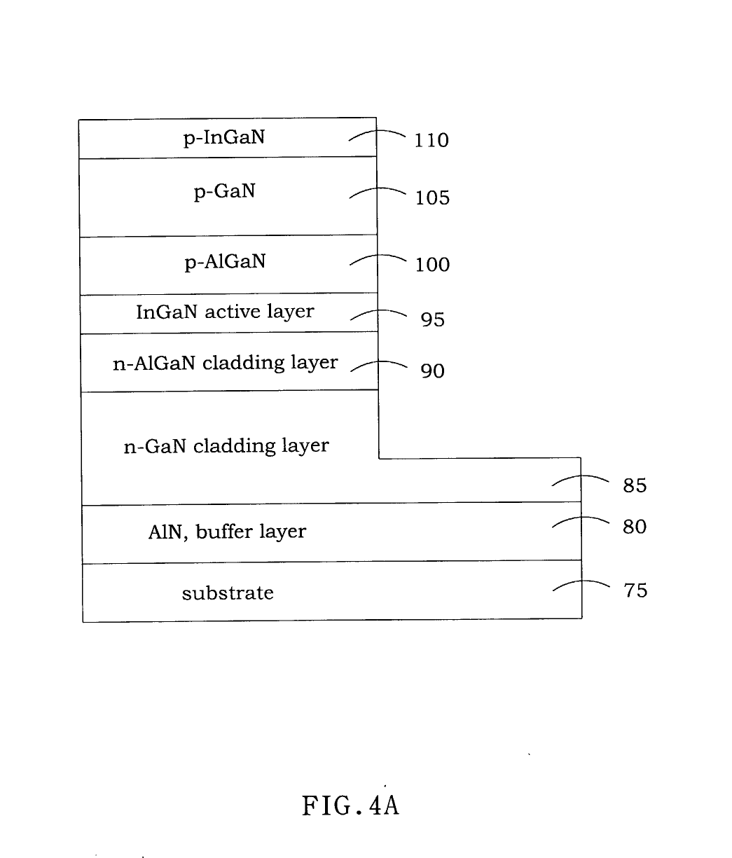

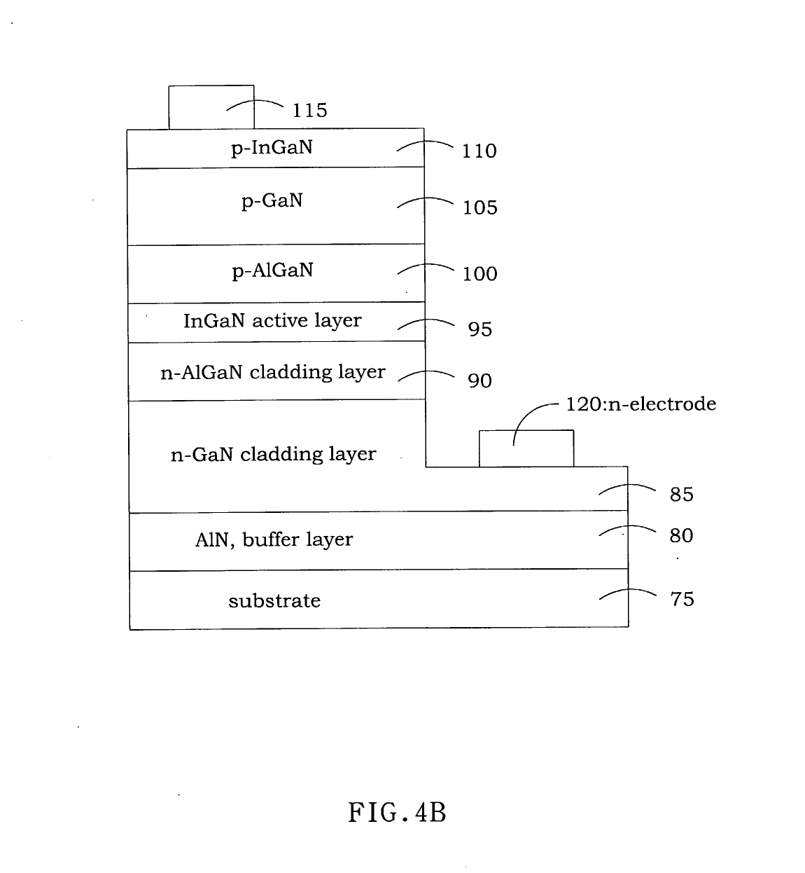

As shown in FIG. 4a, in the above described epitaxial growth process, an etching process is performed in order to expose the n-electrode. In the etching process, after forming an etching mask by photolithography, and removing the unnecessary portions of the p-type GaN layers by RIE (Reactive Ion Etching), the n-type GaN cladding layer 85 is partially exposed.

It is not necessary to exercise the etching process, if the n-electrode has been exposed at other location. After the partial exposing of the n-type GaN cladding layer 85, a first annealing process is carried out following in order to reduce the resistance.

The entire GaN semiconductor 113 is disposed in a nitrogen ambient at about 800° C. for about 20 minutes, so that the p-type layers thereof are activated to reduce the resistance due to the division of the combination of the dopants in the p-type layer, wherein the dopants are Mg, Zn and H.

As shown in FIG. 4B, a metal layer 115 is formed on the p-type InₓGa₁₋ₓN layer 110 to cover a current introducing area. The width of the metal layer 115 is 200 nm to 2000 nm. The metal layer 115 consists of one of the following, Ni, Pt, Pd and Au, and is formed by a conventional method, such as evaporation, sputtering, and electroplating. Particularly, it is preferable to use a metal without hydrogen permeability and having a good characteristic in electrical contact with the p-type InₓGa₁₋ₓN semiconductor layer 110.

On the exposed portion of the n-type GaN cladding layer 85, an n-type electrode 120 is formed by the evaporation of C, Ge, and Au, wherein the thickness of C and Ge is about 50 nm and the thickness of Au is about 200 nm. Thus, a light emitting device process is finished.

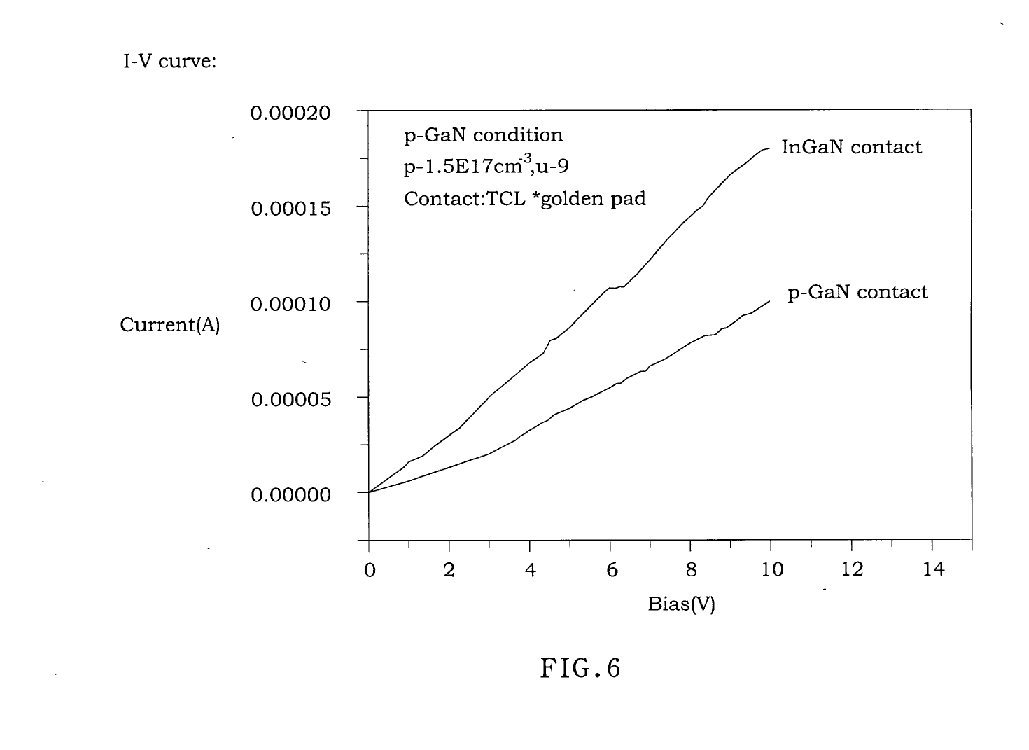

Referred to FIG. 5, FIG. 6, and Table 1, it is easy to find that the contact resistance in the present invention is reduced from 40 KΩ to 14 KΩ, and the sheet resistance is reduced from 79 KΩ/□ to 61 KΩ/□. Therefore, the p-InₓGa₁₋ₓN layer in the structure of this present invention works well exactly as we intended.

Although the above-described embodiment has double hetero structure, the present invention may be applied to other junction structures such as a pn homo-junction diode, hetero structure, and others. The present invention also may be applied to the manufacturing of a unipolar transistor such as FET or laser diodes, and microwave devices.

What is claimed is:

1. A method for manufacturing a semiconductor device with an ohmic contact, said method comprising the following steps of:
providing a growing substrate;
forming a p-type GaN layer onto said substrate;
forming a p-type InₓGa₁₋ₓN layer onto said p-type GaN layer, where 0<x<1; and
forming a metal layer onto said p-type InₓGa₁₋ₓN layer.

2. The method according to claim 1, wherein said substrate comprises a sapphire layer.

3. The method according to claim 1, wherein the step of forming an undoped GaN layer is selected from the group consisting of LPE (Liquid Phase Epitaxy), MOVPE (Metal Organic Vapor Phase Epitaxy) and MBE (Molecular Beam Epitaxy).

4. The method according to claim 1, wherein the step of forming a p-type gallium nitride layer is selected from the group consisting of LPE, MOVPE and MBE.

5. The method according to claim 1, wherein the step of forming a p-type InₓGa₁₋ₓN layer is selected from the group consisting of LPE, MOVPE and MBE.

6. The semiconductor device according to claim 1, wherein said metal layer is selected from the group consisting of Ni, Pt, Pd and Au.

7. The semiconductor device according to claim 1, wherein said p-type gallium nitride layer is a p-type AlₓGa_{y}In_{z}N layer, and 0≦x, y, z≦1, x+y+z=1.

8. A method for manufacturing a light emitting device with an ohmic contact, wherein said method comprises the following steps of:
providing a growing substrate;
forming a buffer layer onto said substrate;
forming an n-type cladding layer onto said buffer layer;
forming an active layer onto said n-type cladding layer;
forming a p-type cladding layer onto said active layer;
forming an p-type indium gallium nitride (InₓGa₁₋ₓN ) layer, where 0<x<1, onto said p-type cladding layer; and
forming a metal layer onto said p-type InₓGa₁₋ₓN layer.

9. The method according to claim 8, wherein said substrate comprises a sapphire layer.

10. The method according to claim 8, wherein said buffer layer is an AlN layer.

11. The method according to claim 8, wherein said n-type cladding layer is an n-type GaN cladding layer.

12. The method according to claim 11, further comprising a n-type AlN cladding layer formed on said n-type GaN cladding layer.

13. The method according to claim 8, wherein said active layer is an InGaN active layer.

14. The method according to claim 8, wherein said p-type cladding layer is a p-type AlGaN cladding layer.

15. The method according to claim 8, further comprising a transparent electrode layer formed on said metal layer.

16. A semiconductor device with an ohmic contact, comprises:
a growing substrate;
a p-type gallium nitride layer (GaN) on said substrate;
a p-type indium gallium nitride (InₓGa₁₋ₓN) layer, where 0<x<1, on said p-type gallium nitride layer; and
a metal layer on said p-type InₓGa₁₋ₓN layer.

17. The semiconductor device according to claim 16, wherein said substrate comprises a sapphire layer.

18. The semiconductor device according to claim 16, wherein said p-type gallium nitride layer is p-type AlₓGa_{y}In_{z}N, and 0≦x, y, z≦1, x+y+z=1.

19. The semiconductor device according to claim 18, wherein said p-type GaN layer has a thickness of about 10 nm to 2000 nm.

20. The semiconductor device according to claim 16, wherein said p-type InₓGa₁₋ₓN layer has a thickness of about 5 nm to 1000 nm.

21. The semiconductor device according to claim 16, wherein said metal layer is selected from the group consisting of Ni, Pt, Pd and Au.

22. The semiconductor device according to claim 16, further comprising a transparent electrode layer formed on said p-type InₓGa₁₋ₓN layer.

23. A semiconductor device with an ohmic contact, comprises:
a growing substrate;
a p-type gallium nitride layer on said substrate;
a p-type indium gallium nitride (InₓGa₁₋ₓN) layer, where 0<x<1, on said p-type gallium nitride layer;
a transparent electrode layer on said p-type InₓGa₁₋ₓN layer; and
a metal layer on said transparent electrode layer.

24. The semiconductor device according to claim 23, wherein said substrate comprises a sapphire layer.

25. The semiconductor device according to claim 23, wherein said p-type GaN layer is p-type AlₓGa_{y}In_{z}N, and 023 x, y, z≦1, x+y+z=1.

26. The semiconductor device according to claim 25, wherein said p-type GaN layer has a thickness of 10 nm to 2000 nm.

27. The semiconductor device according to claim 23, wherein said p-type gallium nitride layer has a thickness of 5 nm to 1000 nm.

28. The semiconductor device according to claim 23, wherein said metal layer is selected from the group consisting of Ni, Pt, Pd and Au.

29. A light-emitting device with an ohmic contact, comprises:
a growing substrate;
a buffer layer on said substrate;
an n-type cladding layer on said buffer layer;
an active layer on said n-type cladding layer;
a p-type cladding layer on said active layer;
an p-type indium gallium nitride (InₓGa₁₋ₓN) layer, where 0<x<1, on said p-type cladding layer; and
a metal layer on said p-type InₓGa₁₋ₓN layer.

30. The light-emitting device according to claim 29, wherein said substrate comprises a sapphire layer.

31. The light-emitting device according to claim 29, wherein said buffer layer comprises an AlN layer.

32. The light-emitting device according to claim 29, wherein said n-type cladding layer is an n-type GaN cladding layer.

33. The light emitting device according to claim 32, further comprising an n-type AlGaN cladding layer forming on said n-type GaN cladding layer.

34. The light-emitting device according to claim 29, wherein said active layer is an InGaN active layer.

35. The light-emitting device according to claim 29, wherein said p-type cladding layer is a p-type AlGaN cladding layer.

36. The light emitting device according to claim 35, further comprising a p-type GaN cladding layer formed on said p-type AlGaN cladding layer.

37. The light emitting device according to claim 36, wherein said p-type GaN cladding layer is a p-type AlₓGa_{y}In_{z}N, and 0≦x, y, z≦1, x+y+z=1.

38. The light-emitting device according to claim 44, wherein said p-type GaN layer has a thickness of 10 nm to 2000 nm.

39. The light emitting device according to claim 29, wherein said p-type InₓGa₁₋ₓN layer has a thickness of about 5 nm to 1000 nm.

40. The light-emitting device according to claim 29, further comprising a transparent electrode layer formed on said p-type InₓGa₁₋ₓN layer.

41. The light-emitting device according to claim 34, wherein said metal layer is selected from the group consisting of Ni, Pt, Pd and Au.
